(19) United States
(12) Patent Application Publication
(10) Pub. No.: US 2009/0175706 A1
(43) Pub. Date: Jul. 9, 2009

(54) METHOD AND APPARATUS FOR DETECTING A WAFER POD

(76) Inventors: Nien-Lu Lee, Hsinchu City (TW); Jui-Te Wu, Hsinchu County (TW); Chia-Hsiung Chen, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/970,471

(22) Filed: Jan. 7, 2008

(51) Int. Cl. H01L 21/677

(52) U.S. Cl. 414/217; 414/805

(57) ABSTRACT

A detection method of a wafer pod includes performing an airtight test to the bolt hole on the cam of the wafer pod and determining the cam is abnormal when a result of the airtight test reveals that the bolt hole has an air-leak defect, wherein the bolt hole is positioned in back of the bolt of the cam.

### BACKGROUND OF THE INVENTION

1. Field of the Invention

The present invention is related to a detection method and a detection apparatus of a wafer pod, and more particularly, to a detection method and a detection apparatus of a wafer pod through performing an airtight test to the wafer pod.

2. Description of the Prior Art

Semiconductor process contains performing deposition, photolithography, and etching processes on a semiconductor wafer. Therefore, it is required to provide a high cleanness in the process environments whether storing or transferring wafers so as to ensuring the quality of semiconductor products. In the prior arts, the cleanness design for the semiconductor process conventionally focused on the cleanness control of the whole process environment. However, as the requirement of cleanness degree becomes higher and higher, certain challenges have occurred, such as the cost control of cleanness equipment and control technology of contamination particles. On the other hand, the method of separating wafers from the process environment can reduce the requirement of cleanness equipment of process environment and avoid energy cost, and therefore the cost can be reduced. Accordingly, this separation method has become a master stream in semiconductor factories for keeping wafers clean, which has three main properties: (1) the separation compartment has to be highly clean; (2) the minienvironment (M/E) of the separation technology has to completely prevent contamination materials from entering the separation compartment; and (3) a system for transferring products into or out from the separation compartment or transferring products between process environments with various cleanness is required.

Taking the treatment of 8 inches of wafers as an example, a standard mechanical interface (SMIF) in cooperation with a material loading module of the M/E is usually used to achieve the above-mentioned separation method of wafers. According to the separation method, a plurality of wafers is generally positioned in a cassette, and the cassette can be set in a SMIF pod for being transferred separately. On the other hand, the material loading module contains the SMIF pod, a SMIF-arm that can retrieve the cassette from the SMIF pod and deliver the cassette to a process tool, and an M/E that can prevent contamination materials.

Please refer to FIG. 1, which is a schematic diagram of a conventional wafer pod 10. The wafer pod 10 contains a cover 12 and a chassis 14. The movable latches 16 disposed in the chassis 14 can be moved to pass through the latch opening (not shown) of the cover 12 to lock the cover 12 on the chassis 14 so as to form a separation compartment 18 for setting a cassette. Accordingly, the wafers in the cassette can be separated from the process environment to avoid a contamination to the wafers.

Referring to FIG. 2, FIG. 2 is a schematic diagram of the bottom of the chassis 14 shown in FIG. 1. The chassis 14 comprises an outer door 24 positioned on the bottom surface of the chassis 14 to cover the inner mechanical structures of the chassis 14. The outer door 24 is locked by a plurality of screws 26 (usually nineteen screws, while only eight screws 26 are illustrated in FIG. 2). A cam 18 with a circular-plate shape is further disposed inside the chassis 14 for controlling the latches 16 to lock or unlock the cover 12. As shown in FIG. 2, the cam 18 in the chassis 14 is covered by the outer door 24, and a portion of the cam 18 is exposed by the circular opening 28 of the outer door 24. As a result, if an operator wants to see the whole cam 18, all the screws 26 have to be dismantled for removing the outer door 24.

FIGS. 3-4 are schematic diagrams of the top view and bottom view of the cam 18 shown in FIG. 2. The cam 18 comprises two cylinder bolts 20 and two bolt holes 22 positioned in back of the bolts 20. When an operator wants to load a cassette into the wafer pod 10, he has to insert bolt probes of the material loading module into the bolt holes 22 to rotate the cam 18 to actuate the latches 16 to move back from the latch holes of the cover 14 so that the cover 12 of the wafer pod 10 is unlocked and can be opened for loading the cassette. After loading the cassette, the cover 12 is covered back on the chassis 14 and the bolt probes are used again to reversely rotate the cam 18 so that the latches 16 moves outward to pass through the latch holes of the cover 12 to lock and seal the cover 12, such that the cassette and the wafers positioned therein can be separated from the process environments. As a result, the wafers are kept in a clean separation compartment in the wafer pod 10 while they are being transferred. As mentioned above, the cam 18 plays an important role in the wafer pod 10. If the cam 18 is damaged, especially when one of the bolts 20 is broken, the cover 12 will easily depart from the chassis 14 of the wafer pod 10, causing the wafers to fall down and break and that brings unexpected cost loss.

Generally, the normal lifetime of a wafer pod 10 may be five years. However, the usage frequency and artificial operation factor of each wafer pod 10 is different, and therefore the real lifetime of every wafer pod 10 may be various. Statistically, about more than 95% of wafer pods 10 in an eight-inch wafer factory may have a real lifetime of about six to nine years. Accordingly, it is required to provide an effective detection method to sift abnormal wafer pods 10 from normal wafer pods 10 without an automatically retirement procedure of the wafer pods 10 in order to prevent abnormal wafer pods 10 from being continuously used, which may cause wafers to fall out from the wafer pods 10 and break by accident.

Usually, a break of the bolt 20 of the cam 18 is most common and is the main cause of the damage of a wafer pod 10. However, since the cam 18 is positioned inside the chassis 14 and covered by the outer door 24, it is not easy to directly perform a visual inspection or other detections to the cam 18. If an inspector wants to visually check if the cam 18 is broken or has a crack, he has to dismantle the nineteen screws 26 on the bottom of the chassis 14 and removes the out door 24 to see the entire cam 18 so as to perform the inspection. Even so, the visual inspection is still not effective to find out a tiny crack or split on the cam 18. In addition, the work of dismantle all the screws 26 and the outer door 24 usually cost about five minutes, which does not meet the efficiency requirement and may cause unexpected operation or assembly problems. Accordingly, how to find out the damaged wafer pods through a simple detection method as soon as possible is still an important issue for the semiconductor factories.

### SUMMARY OF THE INVENTION

This is a primary objective of the claimed invention to provide a detection method and a detection apparatus of a wafer pod to perform an airtight test to the cam of the wafer pod so that the above-mentioned problem of the visually inspecting method in the prior art with the disadvantages of consumption of time and inefficiency can be solved.

According to the claimed invention, a detection method of a wafer pod is provided, wherein the wafer pod has a cam with at least a bolt and a bolt hole positioned in back of the bolt. The claimed invention detection method comprises providing at least a robe and an air-flow control system that can control the movement of the probe, inserting the probe into the bolt hole, operating the air-flow control system to vary the quantity of air in the bolt hole by the probe, obtaining a measurement pressure value of the probe by the air-flow control system, and comparing the measurement pressure value with a standard pressure value to determine whether the cam is damaged or not.

According to the claimed invention, a detection apparatus of a wafer pod is further disclosed. The wafer pod contains a cam with at least a bolt hole. The claimed invention detection apparatus comprises an airtight test device and an alarm device. The airtight test device can perform an airtight test to the bolt hole, and the alarm device can send a warning signal when an air-leakage defect is found in the bolt hole during the airtight test.

Since a probe is inserted into the bolt hole of the cam for performing the airtight test, it is easy to find out whether the cam is normal or damaged since the measured pressure will be abnormal in comparison with the predetermined standard pressure value when a chink or crack occurs in the bolt hole. Accordingly, the detection process can be carried out through a simple method in a short time to obtain an effective detecting result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional wafer pod.

FIG. 2 is a schematic diagram of the bottom of the chassis shown in FIG. 1.

FIGS. 3-4 are schematic diagrams of the top and bottom of the cam shown in FIG. 2 respectively.

FIG. 5 is a schematic diagram of a detection apparatus for detecting a wafer pod according to the present invention.

FIG. 6 is a process diagram of the detection method of a wafer pod according to the present invention.

FIG. 7 is a process diagram of the detection method of a wafer pod according to another embodiment of the present invention.

### DETAILED DESCRIPTION

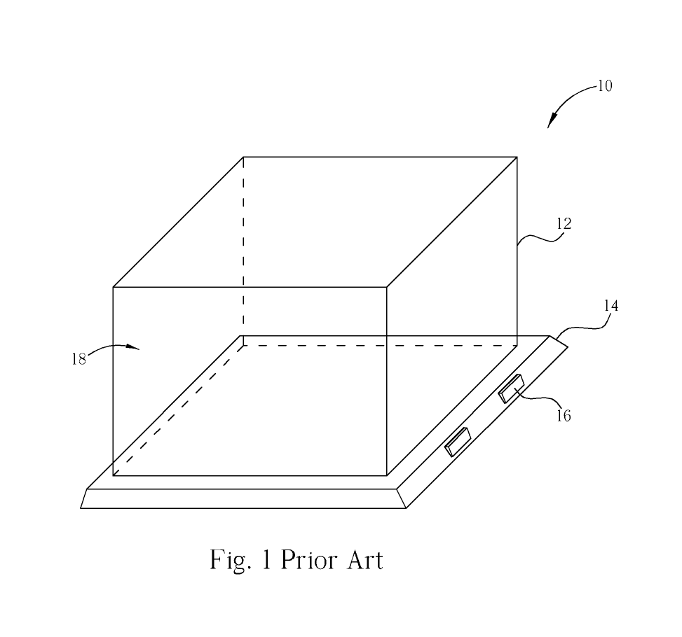

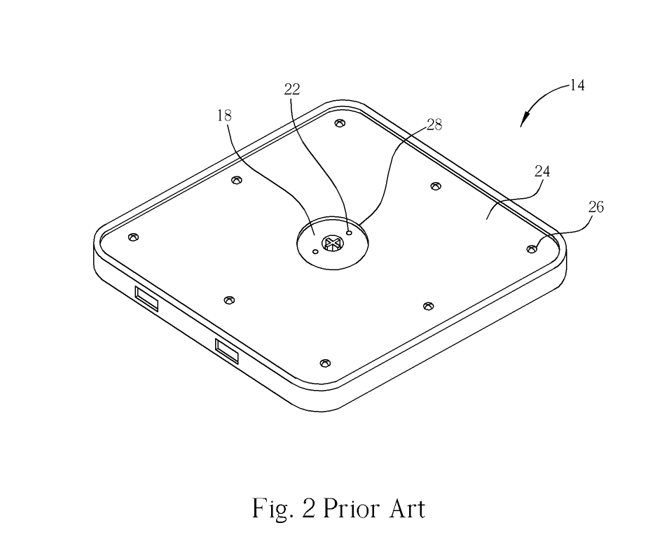

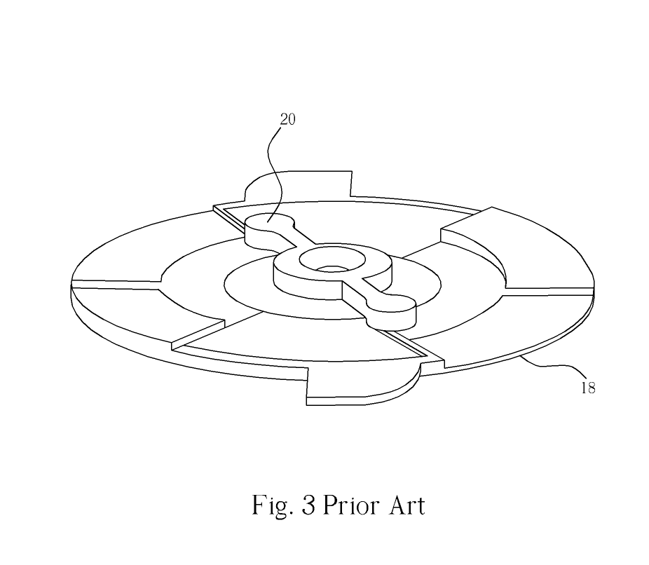

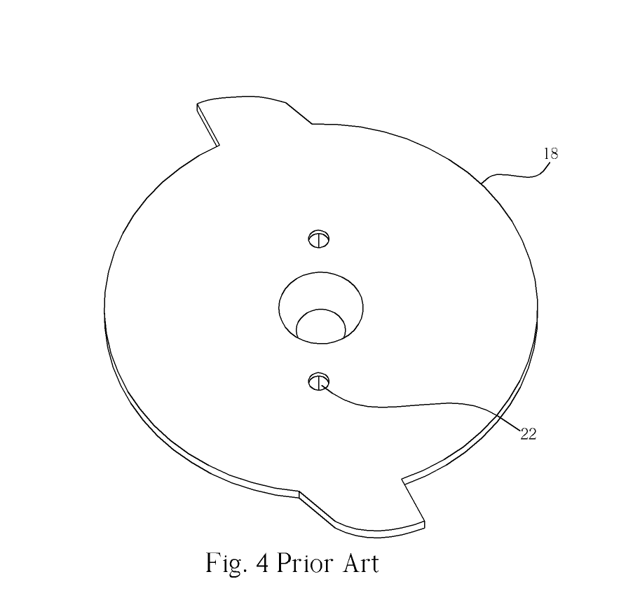

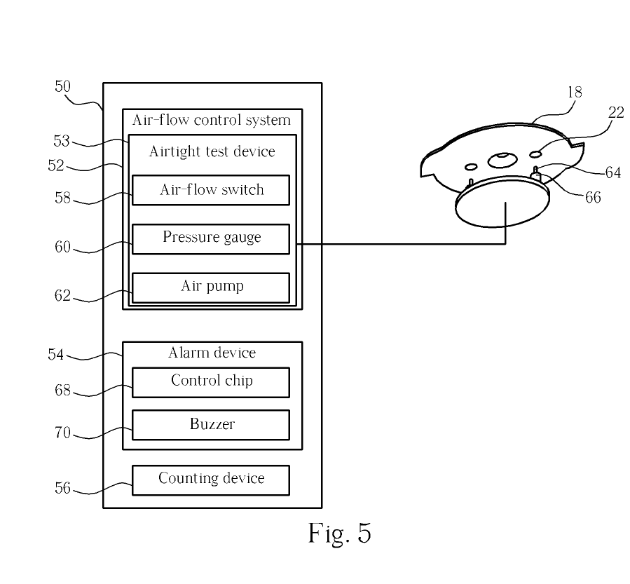

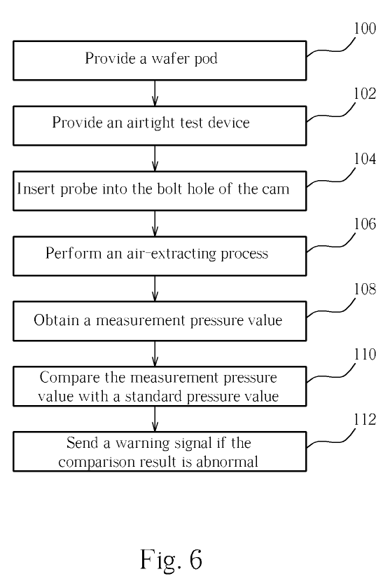

Please refer to FIGS. 5-6. FIG. 5 is a schematic diagram of a detection apparatus 50 for detecting a wafer pod according to the present invention, and FIG. 6 is a process diagram of the detection method of a wafer pod according to the present invention. As shown in FIG. 5, the present invention detection apparatus 50 is used for detecting wafer pods, as the wafer pod 10 shown in FIGS. 1-4, or other SMIF pods. The detection apparatus 50 comprises an air-flow control system 52, an alarm device 54 and a counting device 56. The air-flow control system 52 may comprise an airtight test device 53 which comprises an air-flow switch 58, a pressure gauge 60, and an air pump 62, wherein the air-flow switch 58 may be a solenoid valve that can control the air pump 62. The air-flow control system 52 or the airtight test device 53 of the detection apparatus 50 further comprises two probes 64, and on the bottom of each probe 64 is a rubber o-ring 66. The airtight test device 53 may enable the probes 64 to insert into the bolt holes 22, while each of the rubber o-rings 66 will block the corresponding bolt hole 22 so as to form a closed space in each bolt hole 22. The airtight test device 53 can also control the air pump 62 by the air-flow switch 58 to perform an air-blowing or an air-extracting process to the bolt holes 22. The pressure gauge 60 can detect the variation of the pressure during the air-blowing or air-extracting process. After a predetermined time, the air quantity in each bolt hole 22 will become stable, then a measurement pressure value of the probes 64 or the air pump 62 obtained by the pressure gauge 60 can be transferred to the alarm device 54 for determining whether there is an air-leakage defect occurring in the bolt holes 22 or not. In other embodiments of the present invention, the air-flow switch 58 may be designed as a solenoid valve with a pressure gauge, thus the measurement pressure value can be obtained directly by the solenoid valve. Accordingly, the pressure gauge 60 of the airtight test device 53 shown in FIG. 5 can be omitted.

The alarm device 54 comprises a control chip 68 and buzzer 70, wherein the control chip 68 can compare the measurement pressure value transferred from the airtight test device 53 with a predetermined standard pressure value or a predetermined pressure range. If there is a difference between the measurement pressure value and these predetermined values, the control chip 68 will determine an air-leakage defect is fund out in the bolt holes 22, which means the cam 18 is broken or has a crack. Under this situation, the control chip 68 will actuate the buzzer 70 to produce a warning signal to warn the inspector that the cam 18 under the detection is damaged and has to be retired. In preferable embodiments of the present invention, in order to develop the comparison of the measurement pressure value and the standard pressure value by the control chip 68, the standard pressure value may be represented as a standard voltage value, and the solenoid valve or the pressure gauge 60 my transform the measurement pressure value of the air pump 62 into a voltage value so that the control chip 68 can compare said voltage value with the standard voltage value for determining if the cam 18 is damaged or not. Furthermore, the counting device 56 records the total amount of detected cams of the detection apparatus 50 and the total amount of damaged or abnormal cams so as to make a statistic record for the semiconductor factory, which may be a reference of the retirement plan of devices or equipments in the future.

In addition, in other embodiments of the present invention, the control chip 68 may be included by the airtight test device 53. Accordingly, after the air-flow switch (or solenoid valve) 58 or the pressure gauge 60 obtains the measurement pressure value, it can directly transfer the measurement pressure value to the control chip 68 to determine whether the cam 18 is broken or not. If the detected cam 18 is broken, the control chip 68 will actuate the alarm device 54 to send a warning signal.

As shown in FIG. 6, the detection method of a wafer pod of the present invention comprises the following steps:

Step 100: Provide a wafer pod 10 as shown in FIGS. 1-4, which has a cover 12 and a chassis 14, wherein the chassis 14 contains a cam 18 disposed on the bottom of the chassis 14, and the cam 18 comprises at least a bolt 20 and a bolt hole 22 in back of the bolt 20.

Step 102: Provide an air-flow control system 52 comprising an airtight test device 53 and at least a probe 64, wherein the air-flow control system 52 or the airtight test device 53 can control the actuation of the probe 64.

Step 104: Insert the probe 64 into the bolt hole 22.

Step 106: Operate the air-flow control system 52 to perform an air-extracting process to the bolt hole 22 by the probe 64 so as to vary the air quantity in the bolt hole 22.

Step 108: After processing Step 106 for a predetermined time, obtain a stable measurement pressure value of air-extracting by the air pump 62 as the air quantity in the bolt hole 22 becomes stable.

Step 110: Transfer the operation measurement pressure value of air-extracting to the alarm device 54 and then the control chip 68 compare the measurement pressure value with a predetermined standard pressure value to determine whether the bolt hole 22 has an air-leakage defect or not, and determine the cam 18 is damaged when the comparison result of the measurement pressure value and the standard pressure value is abnormal.

Step 112: Send a warning signal by the buzzer 70 of the alarm device 54 when the detected cam 18 is determined as a broken cam in Step 110 so as to warn the inspector that the cam 18 is damaged.

During Step 106 of carrying out an air-blowing process to the bolt hole 22, the rubber o-ring 66 blocks the opening of the bolt hole 22 so as to form a closed space in each bolt hole 22. In a preferable embodiment, the air quantity in the bolt hole 22 becomes stable after the air-extracting process is performed for 8 to 10 seconds. In the situation of no crack or damage existing in the cam 18 or the bolt hole 22, the pressure of the air-extracting process of the probe 64 will reach a stably great value. As a result, according to the present invention method, a pressure value of the air-extracting process at the 9^{th} to 10^{th} seconds is considered as the above-mentioned measurement pressure value, which will be transferred to the alarm device 54 and compared with the standard pressure value. In a normal case, the measurement pressure value should be larger than or equal to the standard pressure value. In contrast, the pressure of air extracting will be small and the measurement pressure value will be less than the standard pressure value in case of a damage or air-leakage existing in the bolt hole 22. Under this situation, the control chip 68 determines that the cam 18 is abnormal according to this comparison result to actuate the buzzer 70 to produce a warning signal. Therefore, the present invention detection method of cams 18 may be completed in about 10 seconds.

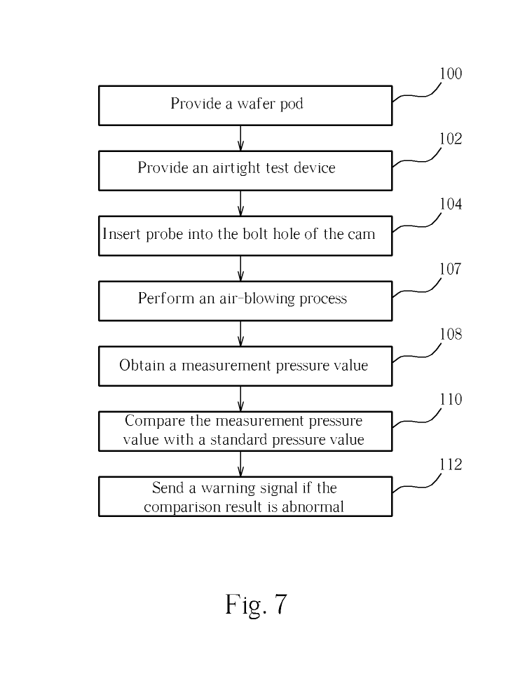

Please refer to FIG. 7, which is a process diagram of the detection method according to a second embodiment of the present invention, wherein the common steps of the second embodiment and the first embodiment are representing with the same numerals. The difference between the first and second embodiments of the present invention is that an air-blowing process is performed in Step 107 for carrying out an airtight test to the cam 18 in this embodiment. Similarly, when the probe 64 blows air to the bolt hole 22, the rubber o-ring 66 will block the opening of the bolt hole 22 to form a closed space. Therefore, after the air-blowing process is performed for about 8 seconds, the air quantity in the bolt hole 22 will become stable and the pressure of air blowing will increase. Then, the airtight test device 53 may transfer the obtained measurement pressure value to the alarm device 54 for the control chip 68 to make a determination. In a normal case, the measurement pressure value should be larger than or equal to the standard pressure value. However, if the measurement pressure value is less than the standard pressure value, the control chip 68 determines that the bolt hole 22 is damaged or has a crack and actuates the buzzer 70 to produce a warning signal.

In other embodiments of the present invention, the comparison for determining the condition of the detected cam 18 may be developed by measuring the air pressure in the bolt hole 22 as the measurement pressure value and by comparing said measurement pressure value with a corresponding standard air pressure value.

In contrast to the prior art, the present invention method of the wafer pod 10 is developed according to an airtight theory for checking if there is a crack or break occurring in the cam 18, thus it only takes about 10 seconds at most to complete the detection process and the total detection process is very simple. Accordingly, the complicated process in the prior art of dismantling nineteen screws 19 and the chassis 14 before the visual inspection of cam 18 can be completely avoided. Furthermore, even there is only a small crack or split on the cam 18, the airtight test could easily inspect out the damage. Accordingly, the present invention method could effectively find out the abnormal cam 18 before the bolt 20 is totally broken, which will cause the abnormal actuation of the latches 16 and damages of wafer falling down from the wafer pod 10.

Those skilled in the art will readily observe that numerous modifications and alterations of the device and method may be made while retaining the teachings of the invention.

What is claimed is:

1. A detection method of a wafer pod, the wafer pod containing a cam with at least a bolt and a bolt hole positioned in back of the bolt, the method comprising:
performing an airtight test to the bolt hole; and
determining the cam is abnormal when a result of the airtight test reveals that the bolt hole has an air-leak defect.

2. The detection method of claim 1, wherein the airtight test comprises:
(a) providing an airtight test device comprising at least a probe and a pressure gauge;
(b) inserting the probe into the bolt hole and forming a closed space in the bolt hole;
(c) performing an air-blowing or air-extracting process to the bolt hole;
(d) obtaining a measurement pressure value of the probe by the pressure gauge; and
(e) providing a standard pressure value, comparing the measurement pressure value with the standard pressure value, and determining the cam is damaged when the comparison result is abnormal.

3. The detection method of claim 2, wherein the step (e) comprises determining the cam is damaged when the measurement pressure value is less than the standard pressure value.

4. The detection method of claim 2, comprising performing the step (d) and step (e) after the step (c) is performed for a predetermined time and an air quantity in the bolt hole become stable.

5. The detection method of claim 4, wherein the predetermined time is about 8 to 10 seconds.

6. The detection method of claim 2, wherein a rubber o-ring is disposed on a bottom of the probe, and the rubber o-ring will block an opening of the bolt hole when the probe is inserted into the bolt hole so as to form the closed space in the bolt hole.

7. The detection method of claim 2, further comprises providing an air-flow control system composed of the airtight test device, the air-flow control system is capable of controlling the operation of the probe.

8. The detection method of claim 7, wherein the air-flow control system comprises an air-flow switch being capable of controlling the probe to blow or extract air.

9. The detection method of claim 2, wherein the standard pressure value is capable of representing as a standard voltage value, and the airtight test device is capable of transforming the measurement pressure value into a voltage value for being compared with the standard voltage value.

10. The detection method of claim 1, further comprising providing an alarm device for sending a warning signal when an air-leakage defect is detected in the bolt hole, and providing a control chip for determining whether the cam or the wafer pod is abnormal or not.

11. The detection method of claim 10, wherein the alarm device further comprises a buzzer for producing the warning signal.

12. The detection method of claim 1, further comprising providing a counting device to make a statistic record of an amount of detected wafer pods and an amount of damaged cams.

13. A detection apparatus of a cam of a wafer pod, wherein the cam comprises at least a bolt hole, the detection apparatus comprising:
an airtight test device being capable of performing an airtight test to the bolt hole; and
an alarm device for sending a warning signal when an air-leakage defect is detected in the bolt hole by the airtight test.

14. The detection apparatus of claim 13, wherein the airtight test device comprises at least a probe which is capable of being inserted into the bolt hole to vary an air quantity in the bolt hole, the airtight test is capable of obtaining a measurement pressure value of the probe, and the alarm device is capable of comparing the measurement pressure value with a standard pressure value to determine whether there is an air-leakage defect in the bolt hole or not.

15. The detection apparatus of claim 14, wherein a rubber o-ring is disposed on a bottom of the probe, and the rubber o-ring will block an opening of the bolt hole when the probe is inserted into the bolt hole.

16. The detection apparatus of claim 14, wherein the airtight test device comprises an air-flow switch, and the air-flow switch comprises a solenoid valve.

17. The detection apparatus of claim 14, wherein the standard pressure value is represented as a standard voltage value, and the airtight test device transforms the measurement pressure value into a voltage value so that the detection apparatus is capable of comparing the voltage value with the standard voltage value.

18. The detection apparatus of claim 13, wherein the airtight test device comprises a pressure gauge.

19. The detection apparatus of claim 13, wherein the alarm device further comprises a buzzer for producing the warning signal.

20. The detection apparatus of claim 13, further comprising a counting device for making a statistic record of an amount of detected wafer pods and an amount of damaged cams.
